(19) United States
(12) Patent Application Publication
(10) Pub. No.: US 2010/0123504 A1
(43) Pub. Date: May 20, 2010

(54) ADAPTIVE LOW NOISE OFFSET SUBTRACTION FOR IMAGERS WITH LONG INTEGRATION TIMES

(76) Inventors: Stefan C. Lauxtermann, Camarillo, CA (US); John C. Stevens, Porter Ranch, CA (US)

Correspondence Address: TELEDYNE;Attn: David Zoetewey, D014, A15, 1049 CAMINO DOS RIOS, THOUSAND OAKS, CA, 91360, US

(21) Appl. No.: 12/271,746

(22) Filed: Nov. 14, 2008

(51) Int. Cl. H03L 5/00

(52) U.S. Cl. 327/331

(57) ABSTRACT

An adaptive low noise offset subtraction pixel and method for adaptive low noise offset subtraction is disclosed. The pixel has a photosensitive element, a current offset memorization circuit and a current subtraction circuit. The current subtraction circuit coupled to the current offset memorization circuit, and comprises a transistor selected from a group consisting of a junction gate field-effect transistor, a bipolar transistor, a MOSFET transistor with a spiral channel, and a MOSFET transistor with a buried channel. The transistor configured to receive an offset current from the current offset memorization circuit and subtract the offset current from an output signal current received from the photosensitive element to provide an offset-free signal current and a shot noise limited subtraction current.

### BACKGROUND

This disclosure relates generally to photo sensors. More specifically, the disclosure relates to an adaptive low noise offset subtraction for imagers with long integration times.

### SUMMARY

An adaptive low noise offset subtraction circuit is disclosed. The circuit includes an integration node, a means for storing and a current subtraction circuit. The means for storing, coupled to the integration node, for storing charge corresponding to an offset current on the integration node prior to signal integration. The current subtraction circuit, coupled to the integration node and means for storing, for subtracting the offset current from an output signal current on the integration node to provide a shot noise limited subtraction current.

In one embodiment, the current subtraction circuit may include a field effect transistor with a high gate area and a small transconductance to provide the shot noise limited subtraction current with low current noise. The transistor may be a junction gate field-effect transistor, a bipolar transistor, a MOSFET transistor with a spiral channel, or a MOSFET transistor with a buried channel. In one embodiment, the current subtraction circuit may also include a cascode stage for increasing impedance of the current subtraction circuit.

The adaptive low noise offset subtraction circuit may also include a direct injection or a buffered direct injection readout amplifier for providing a readout path to the detector signal with an injection efficiency of about 100% while integrating the signal on a high impedance node. In one embodiment, the means for storing comprises a switch and a capacitive divider. The capacitive divider correcting for a voltage swing when the switch is opened.

In one embodiment, a method for adaptive low noise offset subtraction with long integration time is disclosed. The method includes transmitting an offset current having a shot noise from a current source to an integration node prior to a signal integration period, and controlling at least one switch to allow at least one capacitor coupled to the integration node to memorize the offset current. Next, controlling the at least one switch to allow for offset current subtraction at a current sink with low 1/f noise and small transconductance. Then, resetting the integration node using a predetermined reset voltage. An output signal current is then transmitted from the current source to the integration node during the signal integration period. Finally, outputting an offset-free signal current and a shot noise limited subtraction current substantially throughout the signal integration period.

### DRAWINGS

The above-mentioned features and objects of the present disclosure will become more apparent with reference to the following description taken in conjunction with the accompanying drawings wherein like reference numerals denote like elements and in which:

FIG. 1 illustrates an output signal swing with a large constant offset.

FIG. 2 illustrates reduction of achievable integration time in the presence of a large offset.

FIG. 3 illustrates an output signal swing with offset current subtracted, according to an embodiment of the present disclosure.

FIG. 4 illustrates an available integration time with offset current subtracted, according to an embodiment of the present disclosure.

FIG. 5 illustrates an adaptive offset subtraction circuit, according to an embodiment of the present disclosure.

FIG. 6 illustrates a spiral channel for the field effect transistor of FIG. 5, according to an embodiment of the present disclosure.

FIG. 7 illustrates a buried channel for the field effect transistor of FIG. 5, according to an embodiment of the present disclosure.

FIG. 8 illustrates another adaptive offset subtraction circuit with passively cascaded current sink, according to an embodiment of the present disclosure.

FIG. 9 illustrates an adaptive offset subtraction circuit using a bipolar junction transistor, according to an embodiment of the present disclosure.

FIG. 10 illustrates an adaptive offset subtraction circuit using a junction field effect transistor, according to an embodiment of the present disclosure.

FIG. 11 is an exemplary flowchart outlining the operation of an adaptive offset subtraction circuit, according to an embodiment of the present disclosure.

### DETAILED DESCRIPTION

In the description that follows, the present invention will be described in reference to a preferred embodiment that provides adaptive low noise offset subtraction for imagers with long integration times. The present invention, however, is not limited to any particular imaging application nor is it limited by the examples described herein. Therefore, the description of the embodiments that follow are for purposes of illustration and not limitation.

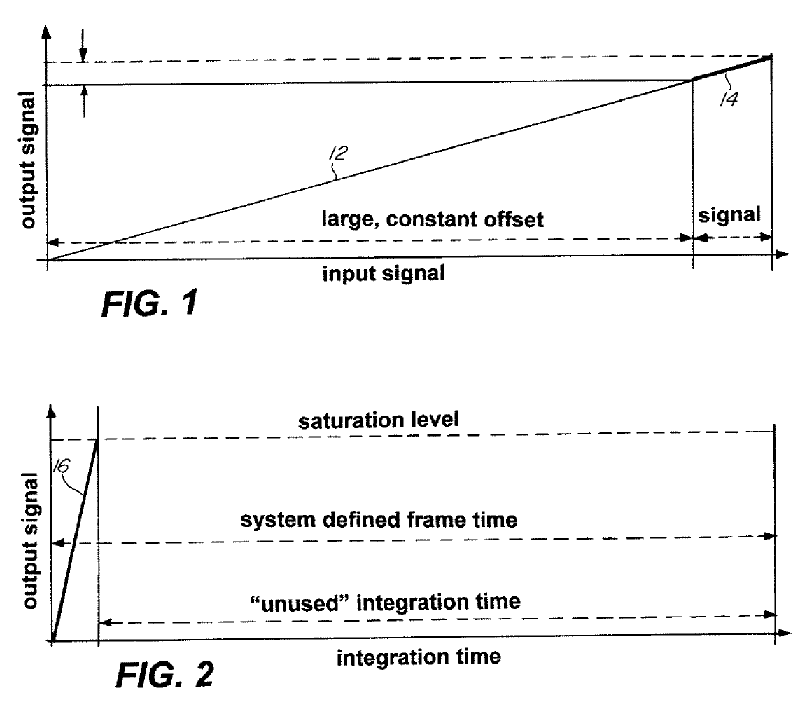

Infrared imagers generally experience large offset currents generated from thermal detector dark current or from a high signal flux emitted by the observed scene itself. This large offset can fill up the capacitance available for integration in a time span shorter than the time required to read out the entire imaging array. However, this offset current is constant within at least 1 frame time, i.e. the time between images in a video camera. FIG. 1 illustrates an output signal swing with a large constant offset. As shown in FIG. 1, the signal output swing 14 is significantly smaller than available analog output swing because of the presence of the large offset current 12. With a low or mild slope for the output signal, the pixel provides low gain and sensitivity. FIG. 2 illustrates an available integration time with a large offset. As shown in FIG. 2, if there is a strong signal flux, it saturates the output signal range 16 in a relatively short period and integration may have to be stopped thereafter with a relatively large “unused” integration time. In such instance, the signal to noise ratio is lower than the physically achievable signal to noise ratio.

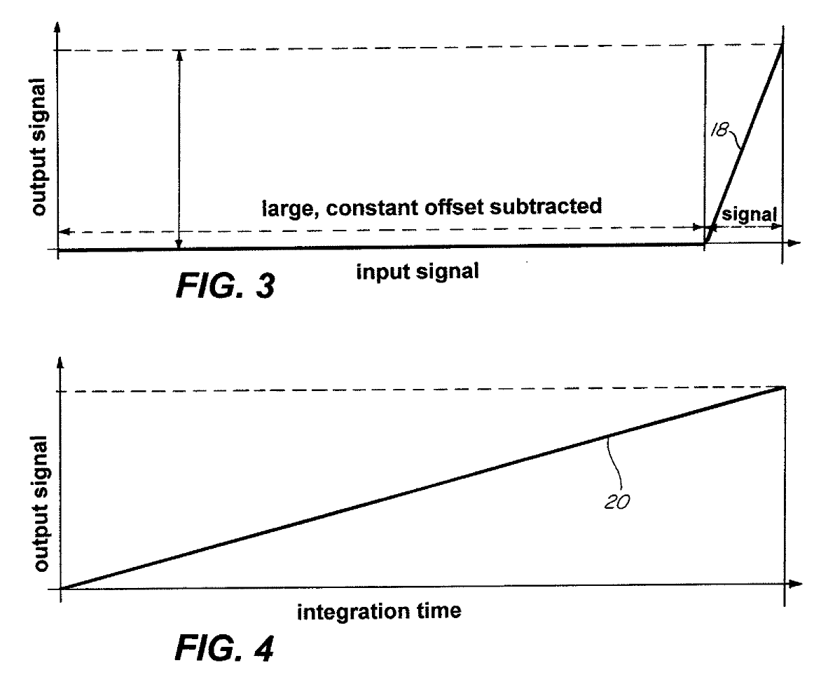

Although a scene has a lot of flux information that can be collected, for example, by staying longer on the scene, the offset current limits the integration time available. Subtracting this offset current with high precision, can increase effective full well or available integration capacitance inside the pixel, which accordingly can collect more signal emitted from a scene. FIG. 3 illustrates an output signal swing with offset current subtracted, according to an embodiment of the present disclosure. As shown in FIG. 3, the signal output 13 has a steeper slope corresponding to higher gain. If offset is subtracted, all the available analog output voltage swing is available for signal output swing 13. FIG. 4 illustrates an available integration time with offset current subtracted, according to an embodiment of the present disclosure. As shown in FIG. 4, all frame time may be used for output signal integration when offset is subtracted. The output signal 20 will not ramp up very quickly so more signal may be collected, and as such, a higher signal to noise ratio may be achieved, i.e. higher contrast can be achieved by the imager.

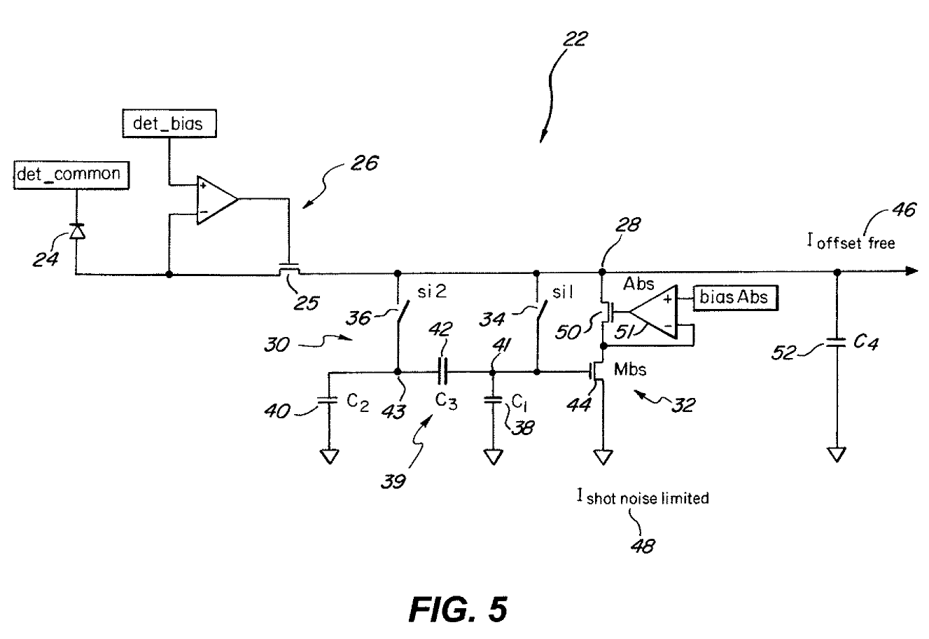

As can be appreciated, an adaptive current subtraction circuit that memorizes offset current when no signal is integrated and subtracts the memorized current thereafter, is provided. FIG. 5 illustrates a schematic of a pixel with an adaptive offset subtraction circuit 22, according to an embodiment of the present disclosure. The adaptive offset subtraction circuit 22 may be implemented in one or more pixels of an imager. The pixel with adaptive offset subtraction circuit 22 may include a photosensitive element 24, a buffered direct injection amplifier 26, an integration node 28, a current offset memorization circuit 30, and a current subtraction circuit 32.

The photosensitive element 24 may be any type of detector, such as an infrared detector, that transmits photo-generated current to the buffered direct injection amplifier 26. The buffered direct injection amplifier 26 may be used to provide a low impedance path for signal charge to flow to the integration node 28 and the current offset memorization circuit 30 rather than back to the photosensitive element 24. As such, the buffered direct injection amplifier 26 may be used to provide an output signal current with an injection efficiency of about 100%. The low impedance path may be about 10 Ω to about 10 kΩ. As can be appreciated, a direct injection amplifier may also be used in place of the buffered direct injection 26 to provide an output signal current with an injection efficiency of about 100%.

The current offset memorization circuit 30 is coupled to the integration node 28 and the photosensitive element 24. The current offset memorization circuit 30 may be configured to receive an offset current from the photosensitive element 24 prior to signal integration and memorize or store the offset current. The current offset memorization circuit 30 may include one or more switches and one or more capacitors. As shown in FIG. 5, the current offset memorization circuit 30 may include a first switch 34, a second switch 36, a first capacitor 38, a second capacitor 40 and a third capacitor 42. In one embodiment, the signal from the photosensitive element 24 is transmitted to the first capacitor 38 where it may be averaged and later stored. The signal is transmitted in the form of a voltage. It flows through the first switch 34 and onto the first capacitor 38. The capacitive divider 39 comprising the first capacitor 38 and the third capacitor 42 may be used to correct for a voltage swing in the current offset memorization circuit 30 when the first switch 34 is opened.

The current subtraction circuit 32 may be coupled to the integration node 28 and the current offset memorization circuit 30. The current subtraction circuit 32 may include a cascode stage 50, for example an NMOS transistor, to increase impedance of the current subtraction circuit 32 towards node 28. The cascode stage 50 may be made active with using an amplifier 51 that increases the effect of the cascode stage 50. The current subtraction circuit 32 may also include a field effect transistor 44 with a buried channel, a spiral channel, or the like, to provide a shot noise limited subtraction current 48. The field effect transistor 44 may be configured to receive the offset current information from the current offset memorization circuit 30 and subtract the offset current from an output signal current received from the photosensitive element 24 to provide the offset-free signal current 46. In one embodiment, the field effect transistor 44 may be further configured to subtract the offset current from the output signal current on the integration node 28 to provide a shot noise limited subtraction current 48.

In operation, a signal may be transmitted from the photosensitive element 24 through the transistor 25 of the direct injection or buffered direct injection amplifier 26, through the first switch 34 to the first capacitor 38. The first switch 34 and the second switch 36 are closed, causing the integration node 28 and nodes 41 and 43 to be shorted and voltage to be memorized in the current offset memorization circuit 30. The field effect transistor 44 may then be turned on to allow all current to flow through the transistor 44 and to ground. Next, the first switch 34 is opened, which will inject charge onto the first capacitor 38. Additionally, kTC noise from the switching operation may also be stored on the first capacitor 38. The combination of the injected charge and the kTC noise creates a voltage offset stored on the first capacitor 38.

After the first switch 34 opened, the voltage on the integration node 28 may increase. Since the second switch 36 is still closed, the voltage across node 43 will also increase. Because node 41 is coupled to node 43 via the third capacitor 42, when voltage on node 43 increases, so does the voltage on node 41. The voltage on node 41 will not increase as much on node 43 because the capacitive divider 39 attenuates the voltage swing on node 43. As the voltage on node 43 increases, more current may be subtracted by the field effect transistor 44. If more current gets subtracted, the output signal on integration node 28 will not slope anymore and will ultimately settle to a constant value, as shown in FIG. 3, when an exact offset current is subtracted.

Next, the second switch 36 is opened, thereby introducing charge on the second capacitor 40. The voltage is also attenuated by the capacitive divider 39 to provide an insignificantly lower voltage signal on node 41 compared to the moment when switch 36 was still closed. The integration node 28 may then be reset to receive an output signal current from the photosensitive element 24. The reset value may, for example, be 300 mV. The transistor 44 may then receive the offset current from the current offset memorization circuit 30 and subtract the offset current from an output signal current received from the photosensitive element 24 to provide the offset-free signal current 46 for integration on the fourth capacitor 52. Throughout the signal integration period, the transistor 44 is subtracting the shot noise limited offset current 48 from the output signal current. As can be appreciated, the offset current is continuously subtracted from the output signal current during reset and signal integration phases.

Offset subtraction may be used to increase the sensitivity of readout amplifiers to small signals in the presence of large offsets. After offset subtraction, the readout amplifier can provide higher gain without saturation, thereby providing a larger output signal. To ultimately improve the signal quality, with the signal quality being quantified in the “signal to noise ratio” number, it may be desired that the current subtraction circuit 32 does not add significant noise contributions beyond the physical limit established by shot noise, inherent to the signal itself. For a current detecting amplifier, the physical noise limit is the shot noise associated with the output current iₛₑₙₛₒᵣ of the photosensitive element 24, with:

iₛₑₙₛₒᵣ=i_{signal}+i_{scene background}+i_{dark current}

The physical noise limit in this case may be:

I²_{n physical limit}=q×iₛₑₙₛₒᵣ

For a practical implementation of such readout circuits, especially for highly integrated sensor array like imagers, CMOS is typically the technology of choice. Unfortunately, conventional NMOS and PMOS transistor of any standard CMOS process suffer from comparatively high 1/f noise, which may become dominant and can corrupt the benefit of a current subtraction circuit 32.

The output current 1/f noise, v_{n1/f}, of the current subtraction circuit 32 may be mathematically described as an input referred noise. The output current noise may be calculated using the transistor's transconductance gₘ as follows:

i_{n1/f}=v_{n1/f}×gₘ

The output current noise is affected not only by the input referred voltage noise v_{n1/f}, but also by the device transconductance gₘ. Since noise v_{n1/f} scales with the inverse of the square root of the gate area, v_{n1/f}˜sqrt(A_{isinc}), where A_{isinc}=W×L, there is a weak dependence that requires a large layout area to be effective. The transistor transconductance in strong inversion gₘₛ and in weak inversion g_{mw} may be provided by the following 2 equations, respectively:

$${g}_{ms} = \sqrt{2 \frac{W}{L} {K}_{P} I}$$

$${g}_{mw} = \frac{qI}{{nk}_{B} T}$$

where Kₚ may be about 300 uA/V for NMOS and about 90 uA/V for PMOS devices in a 0.25 micron CMOS process generation.

A comprehensive expression describing the both regions can be derived as follows:

$${g}_{m} = {g}_{ms} ( 1 - {e}^{- \frac{{g}_{mw}}{{g}_{ms}}} )$$

Due to small offset currents to be subtracted, i.e. ˜10 nA, the subtracting transistor 44 generally operates in weak inversion. In order to reduce the transconductance gₘ and create a low noise current source, it may be desirable to provide a device that operates in strong inversion.

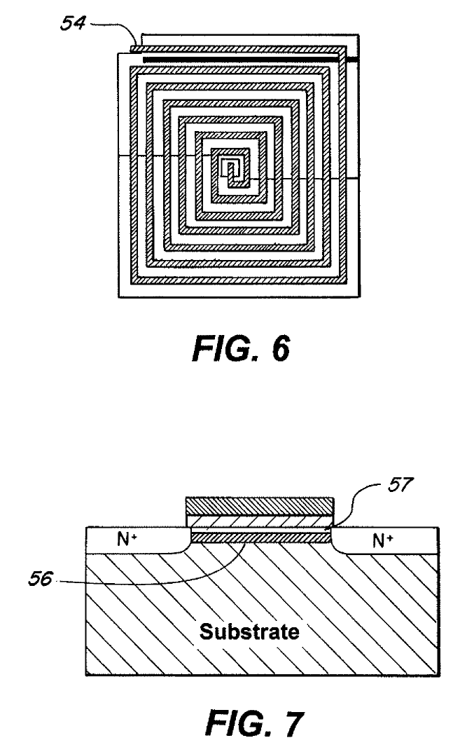

One embodiment that provides such a device is illustrated in FIG. 6. The field effect transistor 44 of FIG. 5 may have a spiral channel 54. This channel 54 may be used to minimize low frequency output current noise by maximizing gate area and minimizing transconductance of the transistor 44. In one embodiment, the gate area may be about 10 to 1000 μm² and the transconductance may be about 1 to 1000 nA/V. The spiral channel 54 may have a low width to length ratio of about 10⁻³. Alternatively, FIG. 7 illustrates a buried channel MOSFET 56 for the field effect transistor 44 of FIG. 5, according to an embodiment of the present disclosure. The buried channel 56, below a shallow implant 57 (i.e. p implant), may also be used to minimize output current noise. As can be appreciated by a person skilled in the art, using the buried channel 56, the spiral channel 54, or the like, the output current noise may be reduced to about 10⁻¹² A.

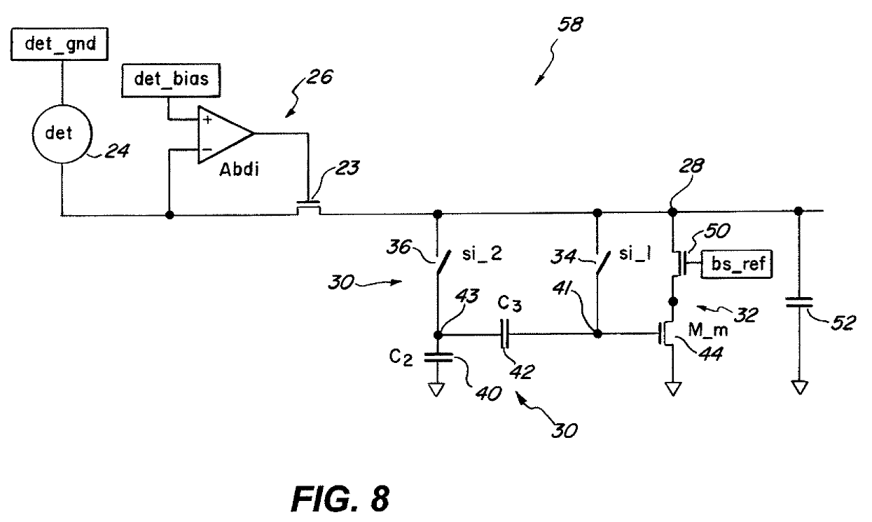

FIG. 8 illustrates another adaptive offset subtraction circuit 58, according to an embodiment of the present disclosure. As shown in the figure, the current subtraction circuit 32 uses the cascode stage 50 without amplifier 51. According to an embodiment, the cascode stage 50 and the amplifier 51 need not be used with the current subtraction circuit 32. Additionally, the first capacitor 38 need not be used with the current offset memorization circuit 30. Instead, the gate capacitance of the field effect transistor 44 may be used to memorize or store the voltage associated with the offset current.

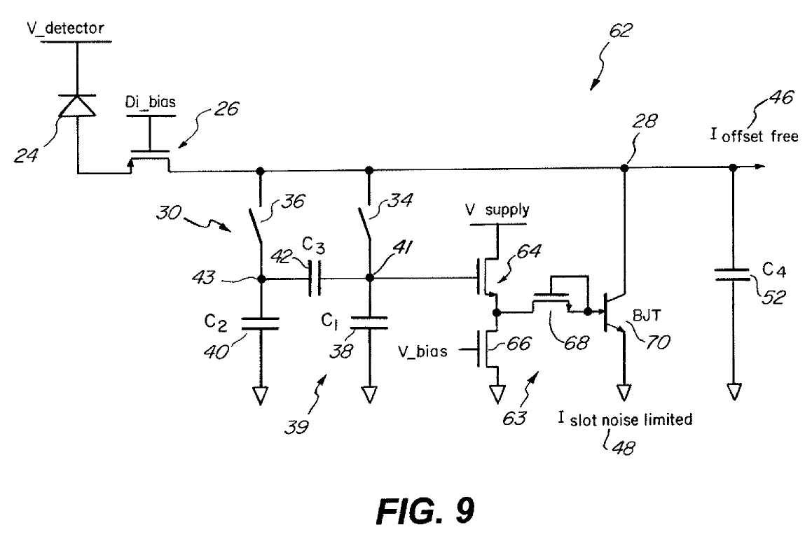

FIG. 9 illustrates an adaptive offset subtraction circuit 62 using a bipolar junction transistor 70, according to an embodiment of the present disclosure. The pixel schematic with adaptive offset subtraction circuit 62 may include photosensitive element 24, buffered direct injection amplifier 26, integration node 28, current offset memorization circuit 30, and a current subtraction circuit 63. Current offset memorization may be performed in the same manner as described for FIG. 5. The signal at node 41 may then pass to the current subtraction circuit 63 to provide a shot noise limited subtraction current 48 and an offset-free signal current 46.

The current subtraction circuit 63 may include a source follower 64, a current source 66 for the source follower 64, a transistor 68 and a Bipolar Junction Transistor (BJT) 70 with small current amplification. The source follower 64 amplifies the signal at node 41 and together with the transistor 68 converts the signal from a voltage to a current. The transistor 68, operating as a resistor, may be an NMOS transistor with a deep subthreshold region that attenuates any noise from source follower 64 and provides a current bias to the BJT 70. The BJT 70 may be configured to receive the offset current from the current offset memorization circuit 30 and subtract the offset current from an output signal current received from the photosensitive element 24 and provide the shot noise limited subtraction current 48 leaving an offset-free signal current 46 for integration on the fourth capacitor 52.

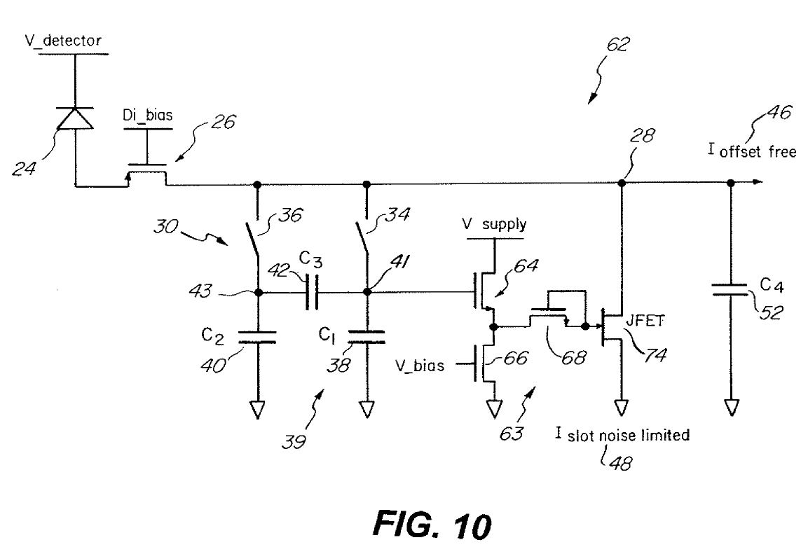

FIG. 10 illustrates an adaptive offset subtraction circuit 72 using a junction field effect transistor 74, according to an embodiment of the present disclosure. The adaptive offset subtraction circuit 72 may include photosensitive element 24, buffered direct injection amplifier 26, integration node 28, current offset memorization circuit 30, and current subtraction circuit 63, as described for FIG. 9. The BJT 70 of FIG. 9 may be substituted with a junction field effect transistor (JFET) 74 with small transconductance to subtract the offset current from an output signal current received from the photosensitive element 24 and provide the shot noise limited subtraction current 48 leaving an offset-free signal current 46 for integration on the fourth capacitor 52.

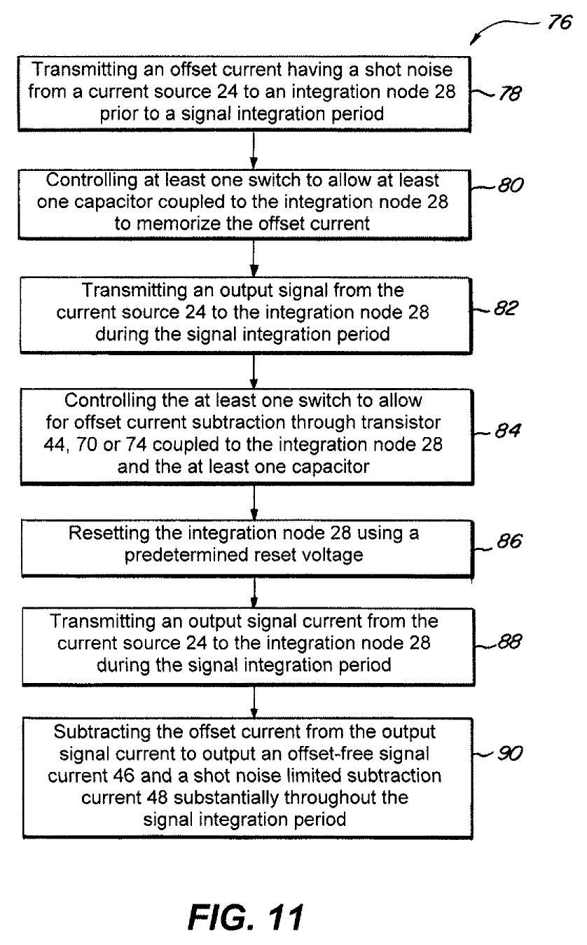

FIG. 11 is an exemplary flowchart 76 outlining the operation of an adaptive offset subtraction circuit, according to an embodiment of the present disclosure. The method begins by transmitting an offset current having a shot noise from a current source 24 to an integration node 28 prior to a signal integration period (78). Next, at least one switch in a switch matrix may be controlled to allow at least one capacitor coupled to the integration node 28 to memorize the offset current (80). An output signal current may then be transmitted from the current source 24 to the integration node during the signal integration period (82). The at least one switch may be controlled again to allow for offset current subtraction through transistor 44, 70 or 74 coupled to the integration node 28 and the at least one capacitor (84). Next, the integration node 28 may be reset using a predetermined reset voltage (86) and an output signal current may be transmitted from the current source 24 to the integration node 28 during the signal integration period (88). Finally, the offset current is subtracted from the output signal current to output an offset-free signal current 46 and a shot noise limited subtraction current 48 substantially throughout the signal integration period (90).

Applications of the present invention may include increased operability of focal plane arrays. For example, offset subtraction for Mercury Cadmium Telluride (MCT) detector arrays with large distribution in dark current reducing yield, may increase the number of useful pixels inside the array. The present invention may also allow for detector operation at higher reverse bias to maximize small signal resistance. Additionally, the present invention may also be used at higher operating temperatures, delivering photovoltaic IR detection without active cooling.

While the adaptive low noise offset subtraction for imagers with long integration times has been described in terms of what is presently considered to be the most practical and preferred embodiments, it is to be understood that the disclosure need not be limited to the disclosed embodiments. It should also be understood that a variety of changes may be made without departing from the essence of the invention. Such changes are also implicitly included in the description. They still fall within the scope of this disclosure. It should be understood that this disclosure is intended to yield a patent covering numerous aspects of the invention both independently and as an overall system and in both method and apparatus modes.

Further, each of the various elements of the invention and claims may also be achieved in a variety of manners. This disclosure should be understood to encompass each such variation, be it a variation of an embodiment of any apparatus embodiment, a method or process embodiment, or even merely a variation of any element of these. Particularly, it should be understood that as the disclosure relates to elements of the invention, the words for each element may be expressed by equivalent apparatus terms or method terms—even if only the function or result is the same. Such equivalent, broader, or even more generic terms should be considered to be encompassed in the description of each element or action. Such terms can be substituted where desired to make explicit the implicitly broad coverage to which this invention is entitled.

It should be understood that all actions may be expressed as a means for taking that action or as an element which causes that action. Similarly, each physical element disclosed should be understood to encompass a disclosure of the action which that physical element facilitates.

It should be understood that various modifications and similar arrangements are included within the spirit and scope of the claims, the scope of which should be accorded the broadest interpretation so as to encompass all such modifications and similar structures. The present disclosure includes any and all embodiments of the following claims.

1. An adaptive low noise offset subtraction pixel comprising:
a photosensitive element;
a current offset memorization circuit coupled to the photosensitive element and configured to receive an offset current from the photosensitive element prior to signal integration and memorize the offset current; and
a current subtraction circuit coupled to the current offset memorization circuit, and comprising a field effect transistor with a channel selected from a group consisting of a buried channel and a spiral channel, the field effect transistor configured to receive the offset current from the current offset memorization circuit and subtract the offset current from an output signal current received from the photosensitive element to provide an offset-free signal current.

2. The adaptive low noise offset subtraction pixel of claim 1, further comprising a buffered direct injection for providing the output signal current with an injection efficiency of about 100%.

3. The adaptive low noise offset subtraction pixel of claim 1, further comprising a direct injection for providing the output signal current with an injection efficiency of about 100%.

4. The adaptive low noise offset subtraction pixel of claim 1, wherein the current offset memorization circuit comprising at least one capacitor for storing charge corresponding to the offset current.

5. The adaptive low noise offset subtraction pixel of claim 1, wherein the current offset memorization circuit comprising a switch and a capacitive divider, the capacitive divider correcting for a voltage swing in the current offset memorization circuit when the switch is opened.

6. The adaptive low noise offset subtraction pixel of claim 1, wherein the current subtraction circuit further comprising a cascode stage for increasing impedance of the current subtraction circuit.

7. The adaptive low noise offset subtraction pixel of claim 1, wherein the photosensitive element is an infrared detector.

8. The adaptive low noise offset subtraction pixel of claim 1, wherein the field effect transistor is a current sink.

9. An adaptive low noise offset subtraction circuit comprising:
an integration node;
means for storing, coupled to the integration node, for storing charge corresponding to an offset current on the integration node prior to signal integration;
a current subtraction circuit, coupled to the integration node and means for storing, for subtracting the offset current from an output signal current on the integration node to provide a shot noise limited subtraction current.

10. The adaptive low noise offset subtraction circuit of claim 9, wherein the current subtraction circuit comprises a field effect transistor with a channel having a low width to length ratio.

11. The adaptive low noise offset subtraction circuit of claim 10, wherein the means for storing comprises a gate capacitance of the field effect transistor.

12. The adaptive low noise offset subtraction circuit of claim 9, wherein the current subtraction circuit comprises a field effect transistor having a high gate area and a small transconductance to provide the shot noise limited subtraction current with low current noise.

13. The adaptive low noise offset subtraction circuit of claim 9, further comprising a buffered direct injection for providing a low impedance path for the output signal current.

14. The adaptive low noise offset subtraction circuit of claim 9, wherein the means for storing comprising at least one capacitor for storing charge corresponding to the offset current.

15. The adaptive low noise offset subtraction circuit of claim 9, wherein the means for storing comprising a switch and a capacitive divider, the capacitive divider correcting for a voltage swing when the switch is opened.

16. The adaptive low noise offset subtraction circuit of claim 9, wherein the current subtraction circuit comprises a cascode stage for increasing impedance of the current subtraction circuit.

17. The adaptive low noise offset subtraction circuit of claim 9, wherein the current subtraction circuit comprises a transistor selected from a group consisting of a junction gate field-effect transistor, a bipolar transistor, a transistor with a spiral channel, and a transistor with a buried channel.

18. The adaptive low noise offset subtraction circuit of claim 9, wherein the photosensitive element is an infrared detector.

19. The adaptive low noise offset subtraction circuit of claim 9, further comprising a signal integration capacitor coupled to the integration node.

20. A method for adaptive low noise offset subtraction with long integration time, the method comprising:
transmitting an offset current having a shot noise from a detector to an integration node prior to a signal integration period;
controlling at least one switch to allow at least one capacitor coupled to the integration node to memorize the offset current;
transmitting an output signal current from the detector to the integration node during the signal integration period; and
controlling the at least one switch to allow for offset current subtraction through a transistor, coupled to the integration node and the at least one capacitor, for subtracting the offset current from the output signal current to provide a shot noise limited subtraction current.

21. The method of claim 20, further comprising buffering the output signal current from the detector using a buffered direct injection.

22. The method of claim 20, wherein the detector is an infrared detector.

23. The method of claim 20, wherein the transistor is a selected from a group consisting of a junction gate field-effect transistor, a bipolar transistor, a transistor with a spiral channel, and a transistor with a buried channel.

24. A method for adaptive low noise offset subtraction with long integration time, the method comprising:
transmitting an offset current from a current source to an integration node prior to a signal integration period;
controlling at least one switch to allow at least one capacitor coupled to the integration node to memorize the offset current;
controlling the at least one switch to allow for offset current subtraction at a current sink, coupled to the integration node and the at least one capacitor, the current sink having a high gate area and a small transconductance;
resetting the integration node using a predetermined reset voltage;
transmitting an output signal current from the current source to the integration node during the signal integration period; and
outputting an offset-free signal current substantially throughout the signal integration period.
